(19) United States
(12) Patent Application Publication
(10) Pub. No.: US 2006/0244151 A1
(43) Pub. Date: Nov. 2, 2006

(54) OBLIQUE RECESS FOR INTERCONNECTING CONDUCTORS IN A SEMICONDUCTOR DEVICE

(75) Inventors: CHEN-HUA YU, Hsin-Chu (TW); CHENG-LIN HUANG, Hsinchu City (TW); SHAU-LIN SHUE, Hsinchu (TW); CHING-HUA HSIEH, Hsinchu (TW); SHING-CHYANG PAN, Hsinchu County (TW); HSIEN-MING LEE LEE, Changhua (TW); HSUEH-HUNG FU, HsinChu (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 10/908,204

(22) Filed: May 2, 2005

(51) Int. Cl. H01L 23/48

(52) U.S. Cl. 257/774; 257/E21.577

(57) ABSTRACT

Semiconductor devices having an oblique metal recess for receiving metal during metallization processes are described. In one example, a semiconductor device includes a dielectric layer formed over a conductive pad disposed in a substrate. The conductive pad is etched to include an oblique recess, which interfaces with a metal deposited during a metallization process. Related methods for forming such metal contacts and interconnections for the semiconductor device are also described.

### TECHNICAL FIELD

Disclosed embodiments herein relate generally to semiconductor devices, and more particularly to semiconductor devices having improved metal contacts and interconnections. Related methods for forming such contacts and interconnections are also described.

### BACKGROUND

Semiconductor devices undergo various processes during manufacture, including metallization processes associated with forming metal contacts and interconnections. Such processes involve the formation of conductive lines to establish electrical communication between various conductive portions of a semiconductor device.

Semiconductor devices sometimes require vertical connections between stacked interconnect or conductive lines. Accordingly, damascene processes have been developed in which openings are formed in the semiconductor device, thereby defining a path between conductive portions of the semiconductor device. Thereafter, the conductive portion at the bottom of the opening is typically etched to form a recess, which provides a metal contact area for facilitating electrical interconnection. Metal is then deposited into the opening during a metallization process, such as a physical vapor deposition (PVD) process, an ionized-physical vapor deposition (i-PVD) process, a chemical vapor deposition (CVD) process or an electroplating process.

In the past, interconnection processes have involved the formation of openings in a dielectric layer of the semiconductor device to form a path to a conductor, such as a conductive pad, lying underneath the dielectric layer. For example, FIG. 1 illustrates a semiconductor device 10 having a conductive pad 12 disposed in a substrate 14, and a dielectric layer 16 formed about the conductive pad and substrate. An opening 18 is formed in the semiconductor device 10 to create a path to the underlying conductive pad 12. The conductive pad 12 is then etched to form a recess 20 in the conductive pad 12. In prior art arrangements, the recess 20 is formed such that it maintains symmetry across axis Y. Stated differently, the surface defined by the recess 14 is parallel with a top surface 22 of the dielectric layer 16. Metallization methods are then used to deposit metal into the opening, thereby interconnecting conductive portions of the semiconductor device 10.

It has been found that such techniques result in the deposited metal having poor coverage of the semiconductor device surface defined by the opening 18 and recess 20. Referring to FIG. 2, prior art metallization methods may result in deposited metal 24 providing poor coverage of sidewalls 26 of the opening 18, with the metal substantially forming at the bottom of the opening 18 and above the recess 20. Unbalanced coverage can lead to poor electrical conduction, and therefore poor performance and reliability of the semiconductor device 10. Furthermore, with smaller sizes, for instance, less than 0.1 um, the symmetrical recess can suffer high resistance problems, and therefore degraded circuit speed.

### SUMMARY

The present disclosure relates to improved interconnections for semiconductor devices and improved methods for forming metal contacts in facilitating electrical interconnection between conductive portions of semiconductor devices. In one embodiment, a semiconductor device is formed to include a dielectric layer having an opening for receiving metal. The opening is formed over a conductor, such as a conductive pad, which may be disposed in a substrate. The conductive pad is etched to have an oblique recess formed therein. The oblique recess generally provides the conductive pad with an asymmetric orientation about an axis defined through the center of the conductive pad. A metallization process is then performed to deposit metal into the opening and onto the conductive pad, thereby forming an electrical connection between conductive portions of the semiconductor device.

In another embodiment, barrier layers may be utilized during the interconnection processes of the present disclosure. More particularly, a semiconductor device is manufactured to include a dielectric layer formed over a conductor, such as a conductive pad, disposed in a substrate. An opening is then formed in the dielectric layer over the conductive pad in order to provide a path to the conductive pad. After formation of the opening, a barrier layer is deposited into the opening to provide coverage of the sidewalls of the dielectric layer defined by the opening, and also to provide coverage of the conductive pad. The portion of the barrier layer formed over the conductive pad is then etched away to allow access to the conductive pad. Further etching processes are then used to etch a portion of the conductive pad such that the resulting conductive pad has an oblique orientation defined by an asymmetric orientation about an axis defined through the center of the conductor. A second barrier layer is then formed along the sidewalls of the dielectric layer and over the conductive pad to provide further protection for the semiconductor device. A metallization process is then used to deposit metal into the opening, thereby forming an electrical connection between conductive portions of the semiconductor device.

### BRIEF DESCRIPTION OF THE DRAWINGS

Reference is now made to the following descriptions taken in conjunction with the accompanying drawings.

FIG. 1 is a cross-sectional view of a prior art semiconductor device having a symmetrical recess formed in its conductive pad;

FIG. 2 is a cross-sectional view of the semiconductor device of FIG. 1 after metal has been deposited into the opening;

FIG. 3 is a process flow diagram for forming an interconnection between conductive portions of a semiconductor device according to the principles of the present disclosure;

FIG. 4 is a cross-sectional view of a semiconductor device at an initial stage of manufacture according to the process flow of FIG. 3;

FIG. 5A is a cross-sectional view of the semiconductor device of FIG. 4 in which a conductive pad therein has been etched to include an oblique recess having a linear configuration;

FIG. 5B is a cross-sectional view of the semiconductor device of FIG. 4 in which a conductive pad therein has been etched to include an oblique recess having a concave configuration;

FIG. 5C is a cross-sectional view of the semiconductor device of FIG. 4 in which a conductive pad therein has been etched to include an oblique recess having a convex orientation;

FIG. 6 is a cross-sectional view of the semiconductor device of FIG. 5A after metal has been deposited into an opening over the conductive pad;

FIG. 7 illustrates another process for forming an interconnection between conductive portions of a semiconductor device according to the principles of the present disclosure;

FIG. 8 is a cross-sectional view of a semiconductor device at an initial stage of manufacture according to the process flow of FIG. 7;

FIG. 9 is a cross-sectional view of the semiconductor device of FIG. 8 having a barrier layer formed in an opening of the semiconductor device;

FIG. 10 is a cross-sectional view of the semiconductor device of FIG. 9 in which a portion of the barrier layer has been etched away and an oblique recess has been formed in a conductive pad underlying the etched-away portion of the barrier layer;

FIG. 11 is a cross-sectional view of the semiconductor device of FIG. 10 with an additional barrier layer formed therein; and

FIG. 12 is a cross-sectional view of the semiconductor device of FIG. 11 after metal has been deposited into an opening over the conductive pad.

### DESCRIPTION OF THE EMBODIMENTS

FIG. 3 illustrates an exemplary process 30 for forming an electrical interconnection in a semiconductor device according to the principles of the present disclosure. The process 30 generally includes forming a first conductor 32, forming a dielectric layer 34 over the first conductor, forming an opening 36 in the dielectric layer and a portion of the first conductor, and depositing a second conductor into the opening 38 to establish electrical communication between the first and second conductors.

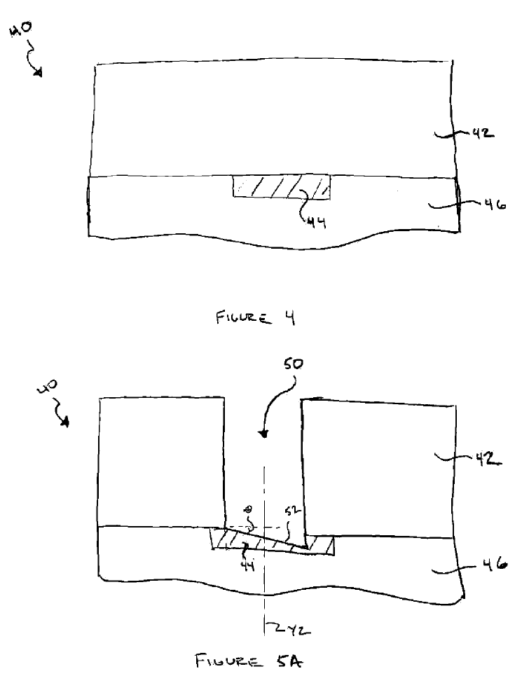

FIGS. 4-6 illustrate an exemplary semiconductor device 40 formed according to the process of FIG. 3. Referring to FIG. 4, the semiconductor device 40 initially includes a dielectric layer 42 formed over a first conductor 44 disposed in a substrate 46. Although not shown, the substrate 46 may include an insulating layer surrounding the first conductor 44. The dielectric layer 42 is preferably a low-k dielectric layer (e.g. with a k-value of less than about 3.4) formed of carbon-doped silicon oxide, fluorine-doped silicon oxide, a combination carbon and fluorine-doped silicon oxide, or organic low-k materials. The first conductor 44 may take the form of a conductive pad formed of any suitable conductive material, such as copper, a metal alloy, or metal nitride.

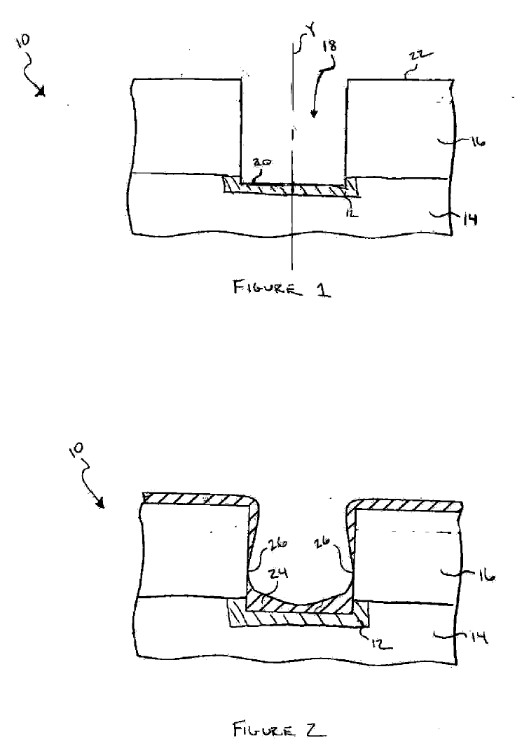

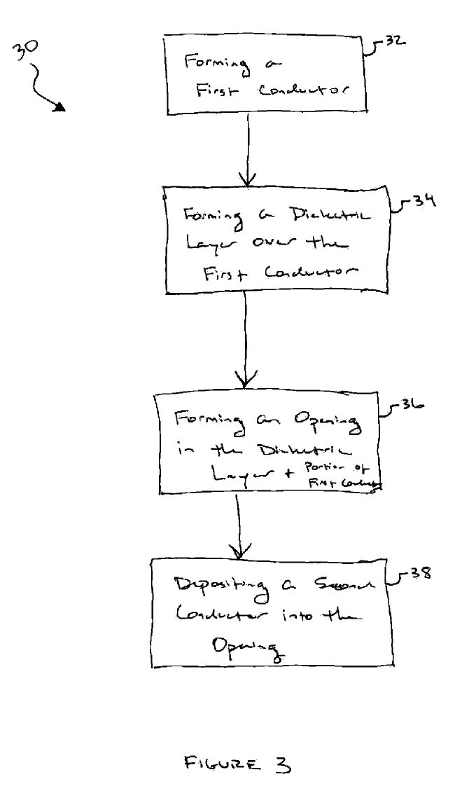

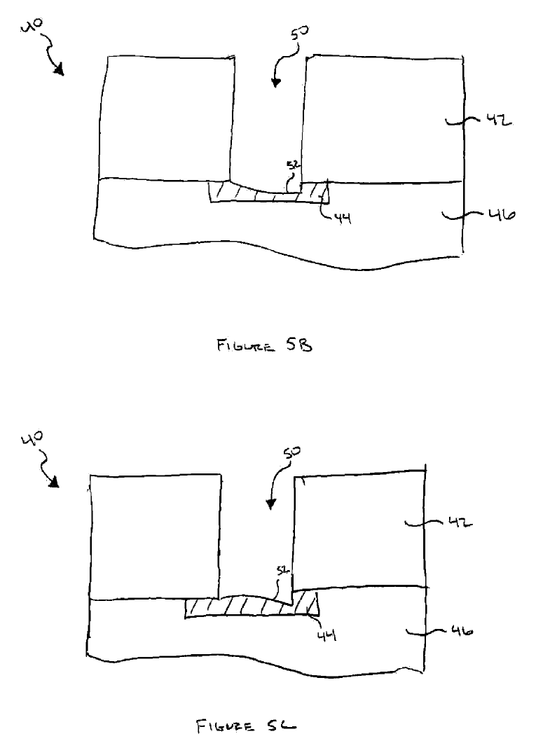

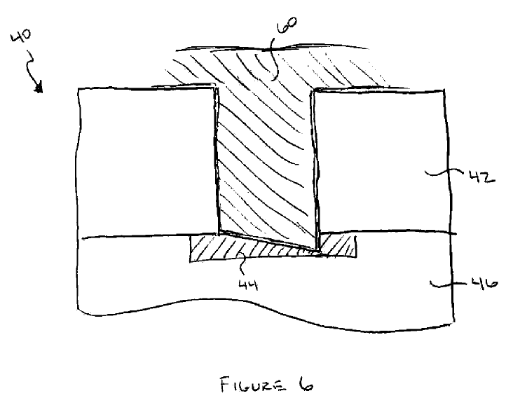

Referring to FIG. 5A, an opening 50 is formed in the dielectric layer 42 over the conductive pad 44 in order to provide a path to the conductive pad. The opening 50 may be formed in a variety of manners such as through damascene processes. In one embodiment, a single damascene process may be used in which a masking layer (not shown) is formed over the dielectric layer and the opening is defined using lithography and plasma etching techniques. Of course, other processes may be used in forming the opening 50, such as a dual damascene process that includes a via hole and trench. The opening 50 is patterned until reaching the conductive pad 44, whereupon etching processes are carried out to form an oblique recess 52 in the conductive pad. In practice, formation of the opening 50 and formation of the oblique recess 52 may take place in a single step or in different steps. The oblique recess 52 reduces crowding effects and therefore reduces joule heating effects. Reduction of joule heating can improve electro-migration and achieve better circuit reliability. The oblique recess 52 also provides more surface area than that of the symmetrical recess 20 in FIG. 1. Increased surface area leads to reduced contact resistance and improved circuit speed.

The recess 52 may take any configuration so long as the shape defined by the recess is asymmetric across axis Y2. For example, in FIG. 5A, the surface of the conductive pad 44 defined by the recess 52 slopes downwardly from left to right in the drawing. In some embodiments, the recess surface may slope at an angle θ, wherein 1°≦θ≦46°. However, other embodiments are contemplated in which the angle θ is defined as 0°<θ<90°. In still further embodiments, the oblique recess 52 may take nonlinear shapes, such as concave shapes (FIG. 5B) and convex shapes (FIG. 5C). Moreover, the direction of downward slope may vary, and is not limited to the left to right direction as depicted in FIGS. 5A-5C. Accordingly, the term “oblique” should be construed as covering all asymmetrical orientations of the recess 52 relative to axis Y2 and covering all orientations in which a tangent line taken along the surface defined by the recess 52 slopes at an angle θ, in which θ is not equal to 0°.

In practice, the etching process used in forming the recess 52 may be a plasma etching process. The recess 52 may be formed to have an oblique shape by applying a plasma etch bombardment or sputtering directed at a desired oblique orientation relative to the conductive pad 44. The sputtering process may involve the use of inert species such as argon or helium to achieve ion bombardment. Also, applying the plasma etch at a relatively low pressure may be beneficial as the plasma etch is better able to control direction at such lower pressures. By directionally etching one portion of the conductive pad 44 at a greater rate than an opposing portion of the conductive pad, an oblique recess can be achieved. For example, with reference to FIG. 5A, the recess 52 may be formed to have a sloping shape by etching the right side of the conductive pad 44 at a greater rate than the left side of the conductive pad. Of course, other etching procedures are contemplated as falling within the scope of this disclosure.

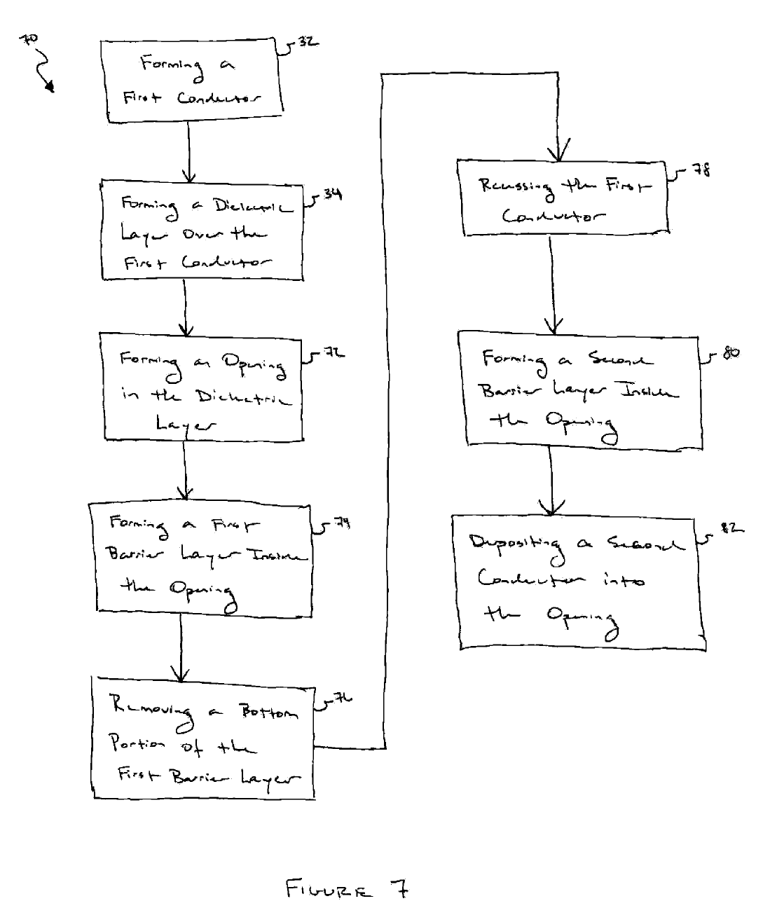

Once the recess 52 has been formed in the conductive pad 44, metallization methods are utilized to deposit a second conductor into the opening 50 and in contact with the conductive pad. In one embodiment, advanced thin-film metallization by PVD, CVD or electrochemical plating methods are used to deposit metal into the opening 50. Referring to FIG. 6, a second conductor 60 is shown deposited into the opening to establish electrical communication from the conductive pad 44 to the second conductor 60. The second conductor 60 may comprise any suitable conductive material, such as copper, copper alloy, aluminum, aluminum alloy, a metal alloy, a metal nitride or combinations thereof. Accordingly, superior electrical performance and reliability are achieved through use of the oblique recess 52 as the metal contact between the first and second conductors.

Various modifications may be made to the general interconnection process 30. For example, the interconnection process 30 may be modified to include the formation of barrier layers inside the opening at various phases of the process. In one embodiment, referring to FIG. 7, the process 30 may be modified to a process 70, which includes formation of an opening 72 in the dielectric layer over the conductive pad and formation of a first barrier layer inside the opening 74. A bottom portion of the first barrier layer is then removed 76 to expose the conductive pad, whereupon a recess is formed by plasma etching or sputtering in the conductive pad 78. Generally the material density of low-k dielectric is much smaller than regular-k, and therefore the sputtering rate of low-k dielectric is much higher than regular-k. In practice, forming the first barrier layer generally protects sidewalls defined by the opening from sputtering damage. In essence, this protection will keep the width of opening 72 substantially unchanged during removal of a bottom portion of the first barrier layer, which can be beneficial for production control. After formation of the recess 78, a second barrier layer is formed inside the opening 80 and over the recessed conductive pad. Finally, a second conductor is deposited into the opening 82 to establish electrical communication between the first and second conductors. The barrier layers may be provided to generally protect the dielectric layer during metallization processes as will be further described.

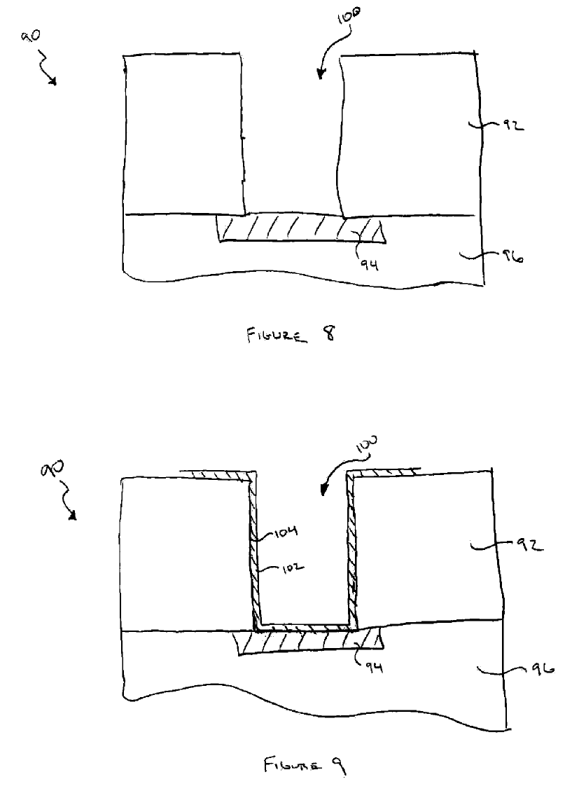

FIGS. 8-12 illustrate an exemplary semiconductor device 90 formed according to the process of FIG. 7. Referring to FIG. 8, the semiconductor device 90 initially includes a dielectric layer 92 formed over a first conductor 94 disposed in a substrate 96. The dielectric layer 92 is preferably a low-k dielectric layer (e.g. with a k-value of less than about 3.4) formed of carbon-doped silicon oxide, fluorine-doped silicon oxide, or a combination carbon and fluorine-doped silicon oxide, or organic low-k materials. The first conductor 94 may take the form of a conductive pad formed of any conductive material, such as copper, a metal alloy, or metal nitride. An opening 100 is then formed in the dielectric layer 92 over the conductive pad 94. The opening 100 may be formed in a variety of manners such as through damascene processes described above.

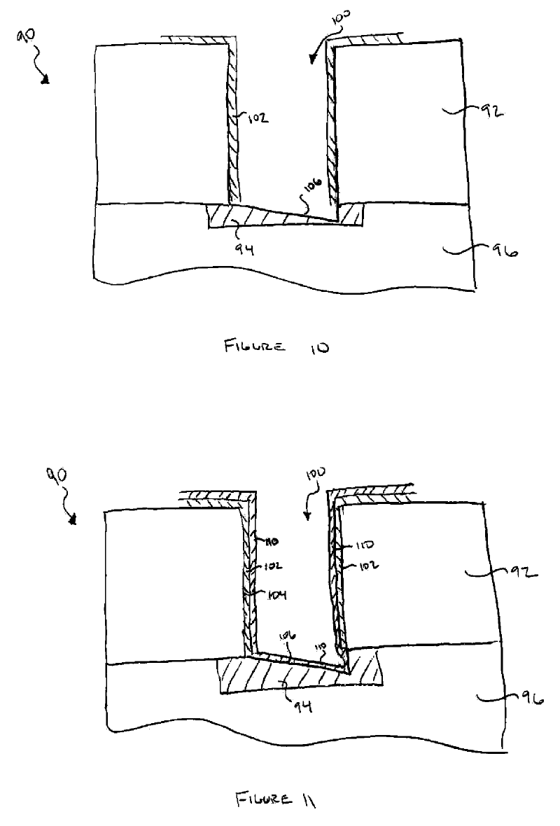

Referring to FIG. 9, a first barrier layer 102 is formed over the conductive pad 94 and along sidewalls 104 defined by the opening 100. A variety of deposition processes may be used in depositing the first barrier layer 102. For example, the barrier layer 102 may be deposited through vapor deposition processes, such as physical vapor deposition (PVD), chemical vapor deposition (CVD), or atomic layer chemical vapor deposition (ALCVD). The first barrier layer 102 may be formed of any material that can provide protection for the dielectric layer 92 against the deleterious effects associated with plasma etching as will be further described. Accordingly, in one embodiment, the first barrier layer 102 is composed of tantalum nitride (TaN). In this embodiment, the thickness of first barrier layer 102 may be from 5 Å to 40 Å, if it is tantalum nitride (TaN) formed by ALCVD, and from 50 Å to 400 Å if it is tantalum nitride (TaN) formed by PVD.

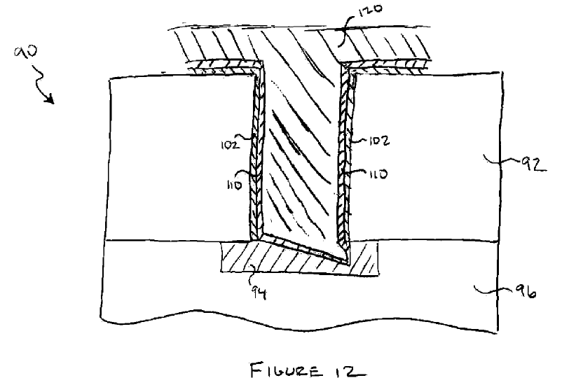

Referring now to FIG. 10, after deposition of the first barrier layer 102, a bottom portion of the first barrier layer is etched away to expose the underlying conductive pad 94. At this point, the conductive pad 94 may then be etched using the above-described plasma etching or sputtering process to form an oblique recess 106 in the conductive pad 94. In practice, the plasma etching process may be used in one step to remove both the bottom portion of the first barrier layer 102 and to form the oblique recess 106 in the conductive pad 94. In some cases, the plasma etching process can have detrimental effects on the integrity of the dielectric layer 92. Accordingly, the first barrier layer 102 provides protection for the dielectric layer 92 during etching of the conductive pad 94. Referring to FIG. 11, a second barrier layer 110 is then deposited into the opening 100 to provide coverage of the first barrier layer 102 along the sidewalls 104 and also to provide coverage of the recessed conductive pad 94.

Metallization methods are then utilized to deposit a second conductor into the opening 100 and in contact with the conductive pad 94. In one embodiment, advanced thin-film metallization by PVD, CVD or electrochemical plating methods are used to deposit metal into the opening 100. Referring to FIG. 12, a second conductor 120 is shown deposited into the opening to establish electrical communication from the conductive pad 94 to the second conductor 120. The resulting interconnection between the conductive pad 94 and the second conductor 120 is an oblique interconnection. One advantage of an oblique interconnection is that a relatively thinner barrier layer may be applied along the sloping interface between the conductors. Accordingly, the second barrier layer 110 may be thinner than prior art barrier layers, thus resulting in superior electrical performance and reliability of the semiconductor device 90. For example, the thickness of second barrier layer 110 may be from 50 Å to 250 Å if it is formed by PVD. Moreover, in some embodiments, the thinner barrier layer 110 can result in an Ohmic reduction of 0.1 to 0.2 ounces per contact.

While various systems and methods for forming metal contacts and interconnections between conductive portions of semiconductor devices according to the principles disclosed herein have been described above, it should be understood that they have been presented by way of example only, and not limitation. For example, the conductive portions described above may include any conductive portions of a semiconductor device, and therefore, are not limited to the conductive pad and deposited metal set forth in the illustrated embodiments. Moreover, the metallization and etching processes described above are merely exemplary, and thus, it is contemplated that other metallization and etching processes may be used in achieving the principles of the present disclosure. Still further, the damascene processes described in connection with forming an opening over the conductive pad are also exemplary. Accordingly, other suitable procedures may be utilized in forming the opening. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A semiconductor device, comprising:
a. a first conductive portion;
b. a dielectric layer formed over the first conductive portion, the dielectric layer being formed of a dielectric having a k-value of less than 3.4, the dielectric layer and the first conductive portion having an opening defined therein, whereby the opening in the first conductive portion defines a recess surface that is oblique relative to an upper surface of the dielectric layer; and
c. a second conductive portion deposited at least partially within the opening and in contact with the first conductive portion, thereby establishing electrical communication between the first and second conductive portions.

2. A semiconductor device according to claim 1 wherein the recess surface is a substantially planar surface extending at an angle relative to the upper surface of the dielectric layer, the angle being defined as θ, wherein 1°≦θ≦46°.

3. A semiconductor device according to claim 1 wherein the recess surface is substantially concave.

4. A semiconductor device according to claim 1 wherein the first conductive portion is formed substantially of copper.

5. A semiconductor device according to claim 1 wherein the second conductive portion is formed substantially of copper.

6. A semiconductor device according to claim 1 wherein the dielectric layer comprises carbon-doped silicon oxide.

7. A semiconductor device according to claim 1 wherein the dielectric layer comprises fluorine-doped silicon oxide.

8. A semiconductor device according to claim 1 wherein the opening is formed via a single damascene process or dual damascene process.

9. A semiconductor device, comprising:
a. a first conductive portion having a recess formed therein, the recess defining a recess surface;
b. a dielectric layer formed over the first conductive portion, the dielectric layer having an opening formed therein, the opening extending through the dielectric layer to form a path to the recess of the first conductive portion, whereby the recess surface is oblique relative to an upper surface of the dielectric layer;
c. a barrier layer deposited at least along sidewalls defined by the opening and the recess surface, the thickness of the barrier layer at a lower portion of the sidewalls being greater than that at the recess surface;
d. a second conductive portion deposited at least partially within the opening and in contact with the portion of the barrier layer overlying the first conductive portion, thereby establishing electrical communication between the first and second conductive portions.

10. A semiconductor device according to claim 9 wherein the recess surface is a substantially planar surface extending at an angle relative to the upper surface of the dielectric layer, the angle being defined as θ, wherein 1°≦θ≦46°.

11. A semiconductor device according to claim 9 wherein the recess surface is substantially concave.

12. A semiconductor device according to claim 9 wherein the recess surface is substantially convex.

13. A semiconductor device according to claim 9 wherein the barrier layer is formed of tantalum nitride and deposited via physical vapor deposition, chemical vapor deposition, or atomic layer chemical vapor deposition.

14. A method for establishing electrical communication between conductive portions of a semiconductor device, comprising:
a. forming a semiconductor device to include a first conductive portion disposed in a substrate, and a dielectric layer formed over the first conductive portion, the dielectric layer having an upper surface;
b. forming an opening in the dielectric layer to create a path to the first conductive portion;
c. forming a first barrier layer in the opening;
d. removing a bottom portion of the first barrier layer in the opening;
e. forming a recess in the first conductive portion, the recess defining a recess surface that is oblique relative to the upper surface of the dielectric layer;
f. forming a second barrier layer on the first barrier layer and the bottom portion of the opening; and
g. forming a second conductive portion on the second barrier layer, thereby establishing electrical communication between the first and second conductive portions.

15. A method according to claim 14 wherein forming an opening and forming a recess are accomplished in different etching processes.

16. A method according to claim 14 wherein depositing the first barrier layer comprises depositing a layer of tantalum nitride.

17. The method of claim 14 wherein depositing the second barrier layer comprises depositing a layer of tantalum nitride.

18. The method of claim 14 wherein forming an opening in the dielectric layer comprises using a single damascene process or a dual damascene process.

19. The method of claim 14 wherein forming a recess in the first conductive portion comprises using a plasma etch or sputtering process.

20. A semiconductor device according to claim 14 wherein the first barrier layer is formed by physical vapor deposition.
